(19) United States
(12) Patent Application Publication
(10) Pub. No.: US 2009/0159125 A1
(43) Pub. Date: Jun. 25, 2009

(54) SOLAR CELL PACKAGE FOR SOLAR CONCENTRATOR

(76) Inventors: Eric Prather, Santa Clara, CA (US); Hing Wah Chan, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 11/962,907

(22) Filed: Dec. 21, 2007

(51) Int. Cl. H01L 31/00

(52) U.S. Cl. 136/259

(57) ABSTRACT

An apparatus may include an integrated circuit package substrate comprising a first surface and a second surface, a solar cell coupled to the first surface of the integrated circuit package substrate, and a light-transmissive element coupled to the second surface of the integrated circuit package substrate. The integrated circuit package substrate and the light-transmissive element form a hermetic seal or a semi-hermetic seal around the solar cell.

### BACKGROUND

1. Field

Some embodiments generally relate to the collection and concentration of solar radiation. More specifically, embodiments may relate to systems to improve the manufacture, durability and/or efficiency of concentrating solar radiation collectors.

2. Brief Description

A concentrating solar radiation collector may receive solar radiation (i.e., sunlight) over a first surface area and direct the received radiation to a second, smaller, surface area. Accordingly, the intensity of the solar radiation within the second area is greater than the intensity within the first area. Existing power systems may leverage this increased intensity to generate electricity in any number of ways.

U.S. Patent Application Publication No. 2006/0266408, entitled “Concentrator Solar Photovoltaic Array with Compact Tailored Imaging Power Units”, describes several types of concentrating solar radiation collectors utilizing unique configurations. Generally, incoming radiation is received by a primary mirror. The primary mirror reflects the received radiation toward a secondary mirror disposed between the primary mirror and the radiation source (e.g., the sun). The secondary mirror, in turn, reflects the radiation toward a photovoltaic (i.e., “solar”) cell, which converts the concentrated radiation to electrical current.

The solar cell comprises a delicate semiconductor integrated circuit die and therefore requires some manner of integrated circuit package. The package may provide environmental protection, heat dissipation, electrical connectivity and/or other functions to the solar cell. The package may also or alternatively provide structure(s) to facilitate proper disposition of the solar cell with respect to optical components of the radiation collector.

Conventional solar cell packages may be susceptible to damage caused by stray concentrated light received at package areas that are not intended to receive light. Moreover, solar cells remain exposed to ambient air within some conventional solar cell packages for use in concentrating solar radiation collectors. Exposure of solar cell junctions to air may decrease reliability of the junctions, and exposed solar cell edges may experience oxidation.

A concentrating solar radiation collector may include an optical element that is optically coupled to its solar cell. The optical element may increase an acceptance angle of the concentrating solar radiation collector, homogenize the concentrated light over the surface of the solar cell, and/or further concentrate the light. A top (i.e., incoming) surface of the optical element should be retained in a particular spatial position relative to other optical elements in the system, and a bottom (i.e., outgoing) surface of the optical element should be retained in a particular spatial position relative to an active aperture of the solar cell. A size and weight of the optical element typically prohibits bonding the optical element directly to the fragile surface of the active aperture.

Improved systems to package a solar cell are desired. Such systems may improve manufacturability, cost, size, solar cell lifetime, optical element alignment, optical element retention, and/or optical coupling quality.

### SUMMARY

To address at least the foregoing, some embodiments provide a system and/or apparatus including an integrated circuit package substrate comprising a first surface and a second surface, a solar cell coupled to the first surface of the integrated circuit package substrate, and a light-transmissive element coupled to the second surface of the integrated circuit package substrate. The integrated circuit package substrate and the light-transmissive element form a hermetic seal or a semi-hermetic seal around the solar cell.

In some aspects, the second surface surrounds the solar cell and is vertically offset from the solar cell. An optical element may be coupled to the light-transmissive element, wherein the light-transmissive element is disposed between the optical element and the solar cell.

The solar cell may include two conductive terminals disposed on an upper side of the solar cell, and the apparatus may further include a first conductive trace disposed on the first surface and electrically coupled to the two conductive terminals. The integrated circuit package substrate may further comprise a vertical portion terminating at the second surface, and one or more conductive vias may be disposed within the vertical portion and electrically coupled to the first conductive trace.

Further to the foregoing aspect, the light-transmissive element may be coupled to a first portion of the second surface, and one or more conductive wires may be coupled to the one or more conductive vias at a second portion of the second surface. The solar cell may additionally comprise a third conductive terminal disposed on a lower side of the solar cell, and a second conductive trace may be disposed on the first surface and electrically coupled to the third conductive terminal.

In addition to the above, the integrated circuit package substrate may comprise a second vertical portion terminating at a third surface, and the apparatus may further comprise a second one or more conductive vias disposed within the second vertical portion and electrically coupled to the second conductive trace, and a second one or more conductive wires coupled to the second one or more conductive vias at a first portion of the third surface, wherein the light-transmissive element is coupled to a second portion of the third surface.

The claims are not limited to the disclosed embodiments, however, as those in the art can readily adapt the description herein to create other embodiments and applications.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a perspective view of an apparatus including an integrated circuit package substrate and a solar cell according to some embodiments.

FIG. 2A is a perspective view of an apparatus including an integrated circuit package substrate and a solar cell according to some embodiments.

FIG. 2B is a cross-sectional diagram of the FIG. 2A apparatus according to some embodiments.

FIG. 2C is a cross-sectional diagram of the FIG. 2A apparatus according to some embodiments.

FIG. 3 is a perspective view of an apparatus including an integrated circuit package substrate and a solar cell according to some embodiments.

FIG. 4A is a perspective view of an apparatus including an integrated circuit package substrate, a solar cell and an optical element according to some embodiments.

FIG. 4B is a cross-sectional diagram of the FIG. 4A apparatus according to some embodiments.

FIG. 5 is a perspective view of a housing for an apparatus according to some embodiments.

FIG. 6 is an exploded perspective view of an array of concentrating solar radiation collectors according to some embodiments.

FIG. 7 is a perspective view of an array of concentrating solar radiation collectors according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

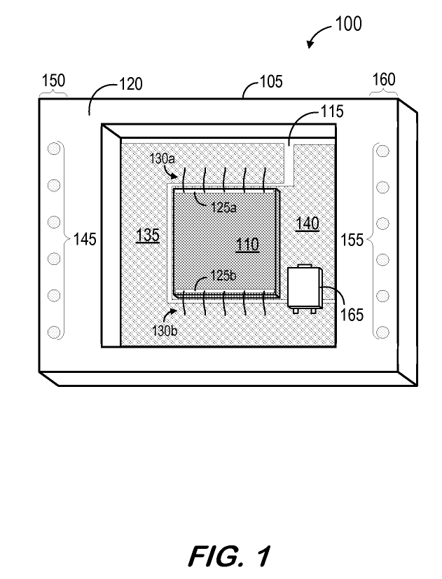

FIG. 1 is a perspective view of integrated circuit package 100 according to some embodiments. Package 100 comprises integrated circuit package substrate 105 and solar cell 110. Some embodiments provide an optical path to solar cell 110 and thermal and electrical paths away from solar cell 110.

Substrate 105 comprises surface 115 and surface 120. According to some embodiments, surface 115 is substantially planar and not coplanar with surface 120. Surface 120 may be substantially planar, but embodiments are not limited thereto. Substrate 105 may comprise a single molded piece of material (e.g., an overmolded leadframe) or may be formed from separate pieces (e.g., a ring of material including surface 120 is joined to a flat piece including surface 115). Such separate pieces need not comprise identical materials.

Solar cell 110 is coupled to surface 115, and surface 120 surrounds solar cell 110 and is vertically offset from the solar cell. Accordingly, surfaces 115 and 120 assist in defining a recess of substrate 105 in which solar cell 110 resides. The coupling of solar cell 110 to surface 115 might not result in physical contact between solar cell 110 and surface 115 due to intermediate elements disposed between solar cell 110 and surface 115. Examples of these intermediate elements according to some embodiments are provided below.

Substrate 105 may comprise a metalized ceramic substrate according to some embodiments. A ceramic substrate may be less susceptible to deterioration due to stray concentrated light than conventional solar cell packaging materials. In some specific embodiments, substrate 105 comprises metalized alumina. Embodiments of substrate 105 may comprise any combination of one or more suitable materials, the selection of which may take into account heat dissipation, thermal expansion, strength and/or other qualities.

Solar cell 110 may comprise a III-V solar cell, a II-VI solar cell, a silicon solar cell, or any other type of solar cell that is or becomes known. Solar cell 110 may comprise any number of active, dielectric and metallization layers, and may be fabricated using any suitable methods that are or become known.

Solar cell 110 is capable of generating charge carriers (i.e., holes and electrons) in response to received photons. In this regard, solar cell 110 may comprise three distinct junctions deposited using any suitable method, including but not limited to molecular beam epitaxy and/or molecular organic chemical vapor deposition. The junctions may include a Ge junction, a GaAs junction, and a GaInP junction. Each junction exhibits a different band gap energy, which causes each junction to absorb photons of a particular range of energies.

Conductive terminals 125a and 125b are disposed on an upper side of solar cell 110. Each of conductive terminals 125a and 125b may comprise any suitable metal contact, and may include a thin adhesion layer (e.g., Ni or Cr), an ohmic metal (e.g., Ag), a diffusion barrier layer (e.g., TiW or TiW:N), a solderable metal (e.g., Ni), and a passivation metal (e.g., Au). Wirebonds 130a and 130b electrically couple conductive terminals 125a and 125b to conductive trace 135. Conductive terminals 125a and 125b therefore exhibit a same polarity according to some embodiments.

A further conductive terminal (not shown) may be disposed on a lower side of solar cell 110. This conductive terminal may exhibit a polarity opposite from the polarity of conductive terminals 125a and 125b. This conductive terminal is coupled to conductive trace 140 according to some embodiments.

Conductive traces 135 and 140 may comprise any suitable conductive materials and may be deposited as shown on substantially planar surface 115 using any suitable techniques. Embodiments are not limited to the illustrated shapes and relative sizes of conductive traces 135 and 140.

Conductive trace 135 is electrically coupled to conductive vias 145. Conductive vias 145 are disposed within a vertical portion of substrate 105 which terminates at portion 150 of surface 120. Similarly, conductive trace 140 is electrically coupled to conductive vias 155, which are disposed within a vertical portion of substrate 105 which terminates at portion 160 of surface 120. According to some embodiments, conductive traces 135 and 140 may extend under portions of surface 120 to facilitate electrical coupling to respective vias 144 and 155.

By virtue of the foregoing arrangement, current may flow between conductive vias 145 and conductive vias 155 while solar cell 110 actively generates charge carriers. If solar cell 110 is faulty or otherwise fails to generate charge carriers, bypass diode 165 may electrically couple conductive trace 135 to conductive trace 140 in response to a received external signal. Bypass diode 165 therefore allows current to flow between vias 145 and 155 and through any external circuit to which vias 145 and 155 are connected.

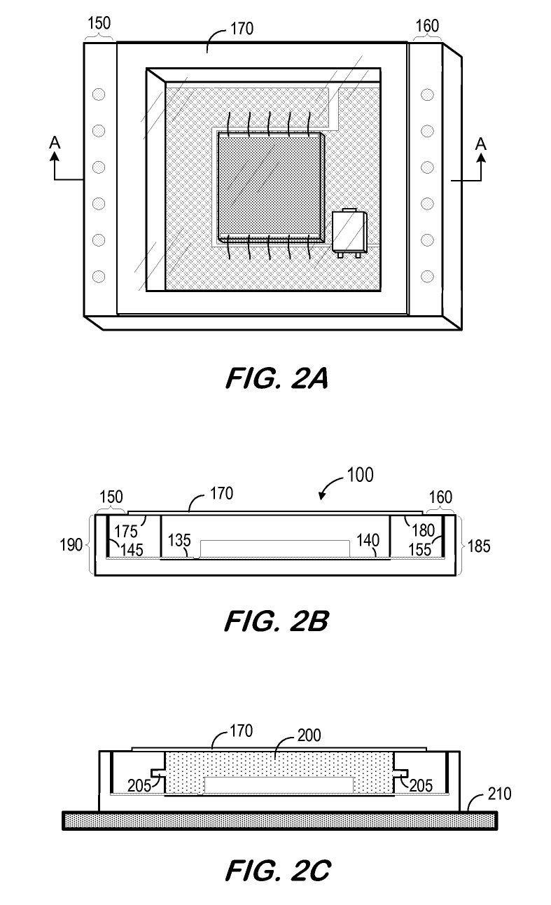

FIG. 2A is a perspective view of integrated circuit package 100 according to some embodiments. Package 100 of FIG. 2A includes light-transmissive element 170 coupled to portions of surface 120. Light-transmissive element 170 may comprise glass and/or any other suitable compound designed to pass wavelengths of light which correspond to the optical characteristics of solar cell 110.

Light-transmissive element 170 may be soldered or frit bonded to substrate 105 according to some embodiments. A composition of light-transmissive element 170 may be selected to match thermal expansion characteristics of substrate 105 and/or cell 110. Element 170 may include an anti-reflective coating in some embodiments.

Light-transmissive element 170 covers portions of surface 120 adjacent to portions 150 and 160, but does not cover portions 150 and 160. Surface 120 may therefore provide support for light-transmissive element 170 and a location for coupling vias 145 and 155 to external circuitry.

FIG. 2B is a view of cross-section A of FIG. 2A. FIG. 2B illustrates vertical portions 185 and 190 of substrate 105, which terminate at portions 150/175 and 160/180, respectively, of surface 120. Light-transmissive element 170 is further shown coupled to portions 175 and 180 of surface 120.

Also shown is conductive trace 140 disposed between solar cell 110 and surface 115. As mentioned above, conductive trace 140 may be electrically coupled to a conductive terminal on a lower side of solar cell 110. Silver die attach epoxy or solder may be used to bond solar cell 110 (and diode 165) to conductive trace 140.

Conductive traces 135 and 140 extend past surface 115 to couple to respective ones of conductive vias 145 and 155. Conductive traces 135 and 140 may comprise any suitable materials in any suitable geometry and may be fabricated using any suitable techniques.

Light-transmissive element 170 and substrate 105 form a hermetic seal or a semi-hermetic seal around solar cell 110 according to some embodiments. For example, package 100 of FIG. 2B may be fabricated in a nitrogen environment to prevent oxidation of exposed junctions of solar cell 110. Semi-hermetic sealing, in this regard, provides negligible performance degradation due to the presence or introduction of undesired compounds over an operational lifetime.

FIG. 2C is a cross-sectional view of the FIG. 2A apparatus according to some embodiments. A volume defined by substrate 105 and element 170 is filled with optically transparent encapsulant 200. Encapsulant 200 may comprise an index-matched optical encapsulant (e.g., silicone, oil) and may therefore provide protection to cell 110 as well as optical continuity between element 170 and cell 110.

FIG. 2C also shows labyrinth 205 defined by substrate 105. Labyrinth 205 may comprise one or more voids within substrate 105 in communication with the volume filled by encapsulant 200. Labyrinth 205 may receive portions of encapsulant 200 as encapsulant 200 expands due to heat generated during operation.

Heatsink 210 may be coupled to a “back” side of substrate 105 using silver die attach epoxy or thermal grease. Heatsink 210 may comprise copper and may facilitate dissipation of heat from substrate 105. Heatsink 210 may also include structures to facilitate mounting of package 100 to a support. Some embodiments may also or alternatively include a heat spreader disposed between solar cell 110 and surface 105. According to some embodiments, substrate 105 itself comprises a heatsink and heatsink 210 is not employed.

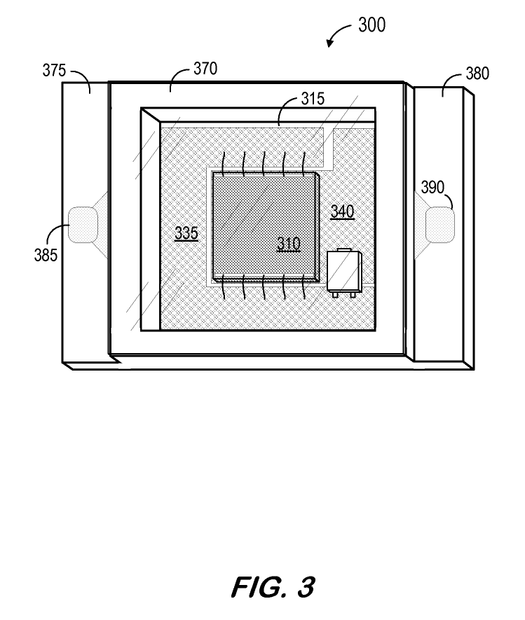

FIG. 3 is a perspective view of package 300 according to some embodiments. As shown, light-transmissive element 370 completely covers an upper surface of substrate 305.

Package 300 also includes extended planar surfaces 375 and 380. Surfaces 375 and 380 may be substantially coplanar with surface 315. Conductive trace 335 extends into surface 375 and terminates at electrical contact 385. Similarly, conductive trace 340 extends into surface 380 and terminates at electrical contact 390. Electrical contacts 385 and 390 may exhibit opposite polarities and may therefore be used to draw current generated by solar cell 310.

According to some embodiments of package 300, a back side of substrate 305 may expose conductive vias which are electrically coupled to conductive traces 335 and 340. The number, polarity and location of conductive terminals, traces and vias are not limited to the configurations described herein.

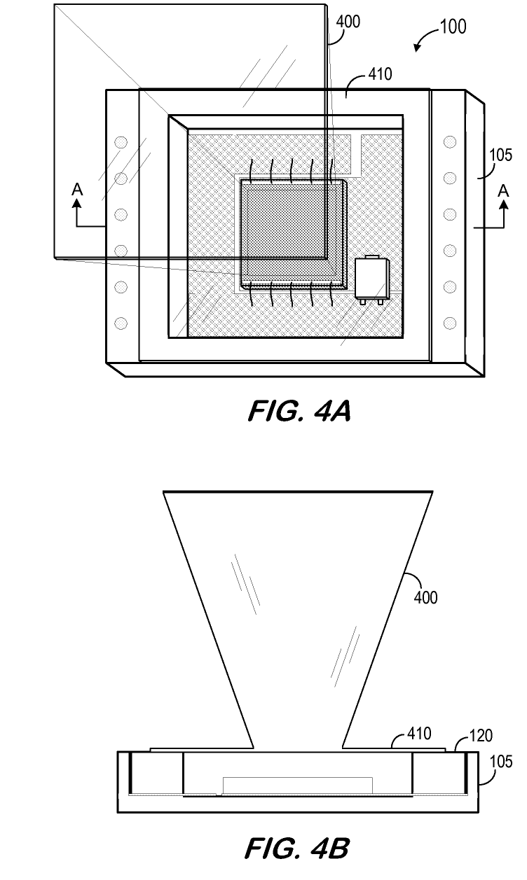

FIG. 4A shows optical element 400 coupled to package 100 according to some embodiments. Optical element 100 may be configured to receive and manipulate desired wavelengths of light and/or pass the light to solar cell 110. For example, solar cell 110 may receive photons from optical element 400 and generate electrical charge carriers in response thereto. Optical element 400 may be deliberately designed to eliminate photons which would not result in electrical charge carriers, thereby reducing an operational temperature and improving the performance of solar cell 110.

Optical element 400 may comprise any suitable composition and shape. According to some embodiments, optical element 400 is integral with light transmissive element 410. Consequently, element 400 is coupled to substrate 105 as a result of coupling element 410 to upper surface 120 of substrate 105.

FIG. 4B is a cross-sectional view illustrating the foregoing arrangement. In some embodiments, optical element 400 is coupled to light-transmissive element 170 before or after element 170 is coupled to surface 120. Optical element 400 may be coupled to light-transmissive element 170 using an index-matched optical bonding agent (e.g., silicone).

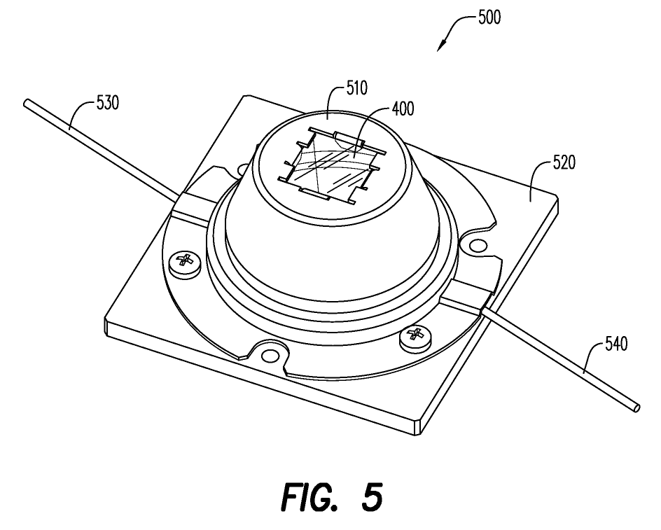

FIG. 5 is a perspective view of apparatus 500 according to some embodiments. Apparatus 500 includes housing 510 for covering and/or retaining optical element 400 of FIGS. 4A and 4B. An upper surface of element 400 remains visible through an opening in housing 400 in order to receive concentrated light. Housing 510 is mechanically mounted to heatsink 520. As mentioned above, heatsink 520 may also be coupled to an integrated circuit package substrate according to embodiments described herein.

Apparatus 500 also includes conductive wires 530 and 540 which are electrically connected to conductive vias of such an integrated circuit package substrate. In some embodiments, the conductive vias described above are coupled to potted and encapsulated pigtail lead wires to which conductive wires 530 and 540 are coupled before housing 510 is fixed 510 to heatsink 520. Conductive wires 530 and 540 may thereby electrically couple a solar cell within housing 510 to external circuitry.

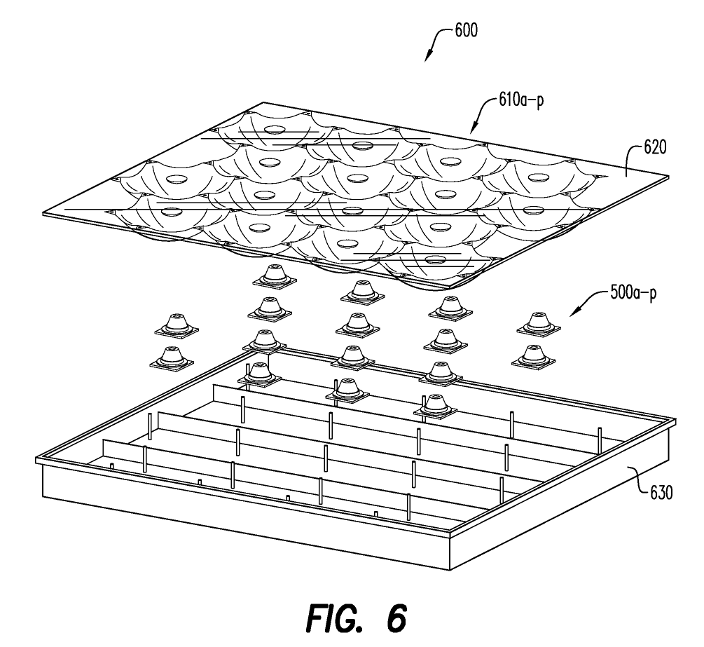

FIG. 6 is an exploded perspective view of apparatus 600 according to some embodiments. Apparatus 600 may generate electrical power from incoming solar radiation. Apparatus 600 comprises sixteen instantiations 500a-p of apparatus 500 of FIG. 5. Wires 530 and 540 of each of apparatuses 500a-p may be connected in series to create an electrical circuit during reception of light by apparatus 600. For clarity, wires 530 and 540 are not illustrated. Embodiments are not limited to the arrangement shown in FIG. 6.

Each of apparatuses 500a-p is associated with one of concentrating optics 610a-p. As described in aforementioned U.S. Patent Application Publication No. 2006/0266408, each of concentrating optics 610a-p includes a primary mirror to receive incoming solar radiation and a secondary mirror to receive radiation reflected by the primary mirror. Each secondary mirror then reflects the received radiation toward an exposed surface of optical rod 400 within a corresponding one of apparatuses 500a-p.

A perimeter of each primary mirror may be substantially hexagonal to allow adjacent sides to closely abut one another as shown. Each primary mirror may comprise low iron soda-lime or borosilicate glass with silver deposited thereon, and each secondary mirror may comprise silver and a passivation layer formed on a substrate of soda-lime glass. The reflective coatings of the primary and secondary mirrors may be selected to provide a desired spectral response to the wavelengths of solar radiation to be collected, concentrated and converted to electricity by apparatus 600.

Each primary mirror and secondary mirror of concentrating optics 610a-p is physically coupled to substantially planar window or cover glazing 620. Each of apparatuses 500a-p is to be coupled to backpan 630. Backpan 630 may comprise any suitable shape and/or materials and may provide strength, electrical routing, and heat dissipation to apparatus 600.

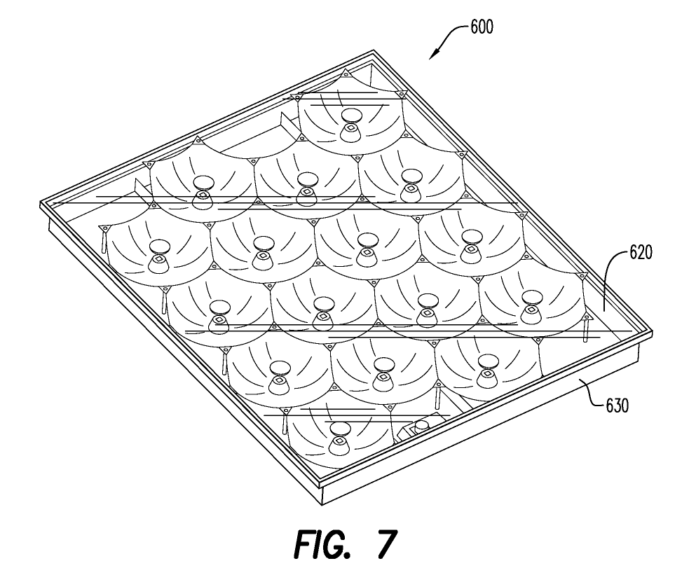

FIG. 7 is a perspective view of assembled apparatus 600 according to some embodiments. As shown, window or cover glazing 620 is secured to backpan 630. Each of apparatuses 500a-p passes through an opening in its corresponding primary mirror and is positioned beneath its corresponding secondary mirror.

The illustrated arrangement allows an exposed surface of each optical element of apparatuses 500a-p to receive concentrated light. As described above, the received light is passed to a corresponding solar cell which generates electrical current in response. The electrical current generated by each of apparatuses 500a-p may be received by external circuitry coupled to backpan 630 in any suitable manner. Assembled apparatus 600 may be mounted on a sun-tracking device to maintain a desired position relative to the sun during daylight hours.

The several embodiments described herein are solely for the purpose of illustration. Embodiments may include any currently or hereafter-known versions of the elements described herein. Therefore, persons in the art will recognize from this description that other embodiments may be practiced with various modifications and alterations.

What is claimed is:

1. An apparatus comprising:
an integrated circuit package substrate comprising a first surface and a second surface;
a solar cell coupled to the first surface of the integrated circuit package substrate; and
a light-transmissive element coupled to the second surface of the integrated circuit package substrate,
wherein the integrated circuit package substrate and the light-transmissive element form a hermetic seal or a semi-hermetic seal around the solar cell.

2. An apparatus according to claim 1, further comprising:
a heatsink coupled to the integrated circuit package substrate, wherein the integrated circuit package substrate is disposed between the solar cell and the heatsink.

3. An apparatus according to claim 1, wherein the first surface and the second surface comprise a single molded piece of material.

4. An apparatus according to claim 1, wherein the solar cell comprises two conductive terminals disposed on an upper side of the solar cell, the apparatus further comprising:
a first conductive trace disposed on the first surface and electrically coupled to the two conductive terminals.

5. An apparatus according to claim 4,
wherein the integrated circuit package substrate comprises a vertical portion terminating at the second surface, and
wherein the apparatus further comprises:
one or more conductive vias disposed within the vertical portion and electrically coupled to the first conductive trace.

6. An apparatus according to claim 5, wherein the light-transmissive element is coupled to a first portion of the second surface; and
the apparatus further comprising:
one or more conductive wires electrically coupled to the one or more conductive vias at a second portion of the second surface.

7. An apparatus according to claim 6, wherein the solar cell comprises a third conductive terminal disposed on a lower side of the solar cell, the apparatus further comprising:
a second conductive trace disposed on the first surface and electrically coupled to the third conductive terminal.

8. An apparatus according to claim 7, wherein the integrated circuit package substrate comprises a second vertical portion terminating at the second planar surface, and
wherein the apparatus further comprises:
a second one or more conductive vias disposed within the second vertical portion and electrically coupled to the second conductive trace; and
a second one or more conductive wires coupled to the second one or more conductive vias at a third portion of the second surface,
wherein the light-transmissive element is coupled to a fourth portion of the second surface adjacent to the third portion.

9. An apparatus according to claim 4, wherein the solar cell comprises a third conductive terminal disposed on a lower side of the solar cell, the apparatus further comprising:
a second conductive trace disposed on the first surface and electrically coupled to the third conductive terminal.

10. An apparatus according to claim 9, further comprising:
a bypass diode coupled to the first conductive trace and to the second conductive trace, the bypass diode to receive a signal to cause the diode to electrically couple the first conductive trace to the second conductive trace.

11. An apparatus according to claim 1, wherein the second surface is substantially planar, surrounds the solar cell, and is vertically offset from the solar cell.

12. An apparatus according to claim 11, further comprising:
an optical element coupled to the light-transmissive element,
wherein the light-transmissive element is disposed between the optical element and the solar cell.

13. An apparatus according to claim 12,
wherein the optical element is integral with the light-transmissive element

14. An apparatus according to claim 11, wherein the integrated circuit package substrate and the light-transmissive element define a volume surrounding the solar cell, the apparatus further comprising:
silicone or oil disposed within the volume.

15. A method comprising:
fabricating an integrated circuit package substrate comprising a first surface and a second surface;
coupling a solar cell to the first surface of the integrated circuit package substrate; and
coupling a light-transmissive element to the second planar surface to form a hermetic seal or a semi-hermetic seal around the solar cell.

16. A method according to claim 15, further comprising:
fabricating a first conductive trace on the first surface; and
electrically coupling the first conductive trace to two conductive terminals disposed on an upper side of the solar cell.

17. A method according to claim 16, further comprising:
fabricating one or more conductive vias electrically coupled to the first conductive trace and disposed within a vertical portion of the integrated circuit package substrate terminating at the second surface;
coupling one or more conductive wires to the one or more conductive vias at a first portion of the second surface; and
coupling a light-transmissive element to a second portion of the second surface.

18. A method according to claim 17, further comprising:
fabricating a second conductive trace on the first surface;
electrically coupling the second conductive trace to a third conductive terminal disposed on a lower side of the solar cell;
fabricating a second one or more conductive vias electrically coupled to the second conductive trace and disposed within a second vertical portion of the integrated circuit package substrate terminating at the second surface; and
coupling a second one or more conductive wires to the second one or more conductive vias at a third portion of the second surface,
wherein the light-transmissive element is coupled to a fourth portion of the second surface adjacent to the third portion.
